(19) United States
(12) Patent Application Publication
(10) Pub. No.: US 2026/0229850 A1
(43) Pub. Date: Aug. 6, 2026

(54) OPTICAL SEMICONDUCTOR DEVICE

(71) Applicant: Lumentum Operations, LLC, San Jose, CA (US)

(72) Inventor: Atsushi NAKAMURA, Komoro (JP)

(21) Appl. No.: 19/249,009

(22) Filed: Jun. 25, 2025

(30) Foreign Application Priority Data
Jan. 29, 2025 (JP) 2025012783
Feb. 28, 2025 (JP) 2025031610

(51) Int. Cl. H01S 5/34; H01S 5/20; H01S 5/343

(52) U.S. Cl. CPC H01S 5/3403; H01S 5/2009; H01S 5/2018; H01S 5/34313; H01S 5/34346

(57) ABSTRACT

An optical semiconductor device includes a multiple-quantum well layer which is formed from one of InGaAsP or InGaAs and which includes a well layer and a barrier layer; an electron barrier layer formed from InAlAs; a spacer layer which is placed between the multiple-quantum well layer and the electron barrier layer, and which is formed from InP; and an optical confinement layer placed between the multiple-quantum well layer and the spacer layer. The electron barrier layer has a highest energy level that is approximately equal to or more than a highest energy level of the optical confinement layer in a valence band.

### CROSS-REFERENCE TO RELATED APPLICATION

This Patent Application claims priority to Japan Patent Application No. JP2025-031610, filed on February 28, 2025, and Japan Patent Application No. JP2025-012783, filed on January 29, 2025. The disclosures of the prior Applications are considered part of and are incorporated by reference into this Patent Application.

### TECHNICAL FIELD

The present disclosure relates generally to an optical semiconductor device.

### BACKGROUND

Optical semiconductor devices used for optical communication include semiconductor lasers which serve as light sources and optical amplifiers which amplify light. In proportion to an increase in amount of optical communication of recent years, semiconductor lasers and optical amplifiers are increasingly desired to have higher power. An increase in optical output intensity in high-temperature operation is particularly desired.

### SUMMARY

Generally speaking, an optical semiconductor device has a structure in which a multiple-quantum well (MQW) layer is sandwiched by an n-type semiconductor layer and a p-type semiconductor layer. A material of the MQW that is used in an InP-based semiconductor laser is InGaAs, InGaAsP, or InGaAlAs in many cases. An InGaAsP-based MQW is known to possess excellent reliability but, in some cases, is inferior to an InGaAlAs-based MQW in an optical output characteristic in high-temperature operation. One of reasons for this inferiority is overflow of electrons from the MQW in high-temperature operation. In some cases, a structure includes, in order to suppress the overflow of electrons, an electron barrier layer placed between the MQW and the p-type semiconductor layer. For example, placing an electron blocking layer formed from InAlAs in an optical semiconductor device that has an MQW formed from InGaAlAs.

An optical semiconductor device that achieves an excellent optical output characteristic in a high-temperature environment and high reliability can be obtained by employing InGaAsP excellent in reliability as the material of the MQW and using InAlAs which effectively suppresses the overflow of electrons as the material of the electron barrier layer. Continuous forming of the MQW and the electron barrier layer by growing a multilayer once is generally demanded in order to maintain crystal quality and quality of a boundary between layers. A drop in crystal quality leads to a drop in reliability and degradation of characteristics. When two layers differing in growth conditions are grown continuously, fine crystal quality fails to be obtained in some cases. However, InGaAsP and InAlAs have growth conditions different from each other. In some cases, the influence of the difference in growth conditions of an InGaAsP layer and an InAlAs layer on crystal quality can be reduced by placing an InP layer between the InGaAsP layer and the InAlAs layer.

Crystal quality can be improved by placing the InP layer between the InGaAsP layer and the InAlAs layer, but another problem arises. That is, whereas the InAlAs layer satisfactorily suppresses the overflow on electrons in a conduction band, a flow of holes is hindered in a valence band by an energy barrier between the InP layer and the InAlAs layer. This results in degradation of the optical output characteristic in high-temperature operation. The same problem may arise when the MQW is formed from InGaAs and InAlAs forms the electron barrier layer.

Some implementations described herein provide an optical semiconductor device that has an excellent optical output characteristic in high-temperature operation.

In some implementations, an optical semiconductor device includes: a multiple-quantum well layer which is formed from one of InGaAsP or InGaAs and which includes a well layer and a barrier layer; an electron barrier layer formed from InAlAs; a spacer layer which is placed between the multiple-quantum well layer and the electron barrier layer, and which is formed from InP; and an optical confinement layer placed between the multiple-quantum well layer and the spacer layer. The electron barrier layer has a highest energy level that is approximately equal to or more than a highest energy level of the optical confinement layer in a valence band.

### BRIEF DESCRIPTION OF THE DRAWINGS

FIG. 1 is a bird's-eye view of a semiconductor laser according to a first example implementation of the present invention.

FIG. 2 is a band diagram of the semiconductor laser illustrated in FIG. 1.

FIG. 3 is a band diagram of a semiconductor laser according to a comparison example.

FIG. 4 is a band diagram of a semiconductor laser according to a second example implementation of the present invention.

FIG. 5 is a band diagram of a semiconductor laser according to a third example implementation of the present invention.

FIG. 6 is a band diagram of a semiconductor laser according to a fourth example implementation of the present invention.

FIG. 7 is a band diagram of a semiconductor laser according to a fifth example implementation of the present invention.

### DETAILED DESCRIPTION

The following detailed description of example implementations refers to the accompanying drawings. The same reference numbers in different drawings may identify the same or similar elements. Elements may not be drawn to scale.

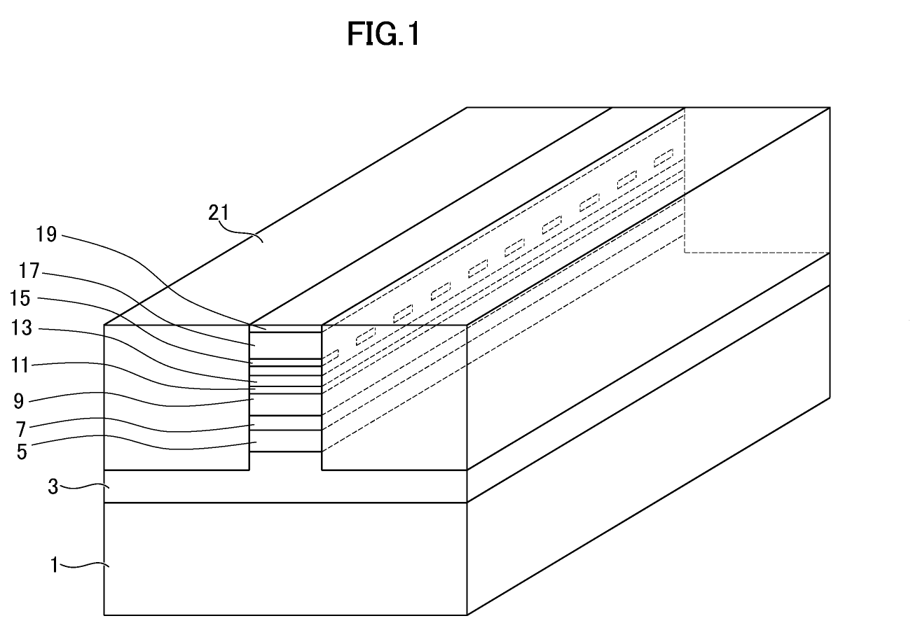

FIG. 1 is a bird's-eye view of an optical semiconductor device according to a first example implementation of the present invention. Description given here takes a semiconductor laser as an example. The semiconductor laser has a semiconductor multilayer structure in which an n-type cladding layer 3, an n-type SCH layer (optical confinement layer) 5, a multiple-quantum well layer (also referred to as “MQW”) 7, a p-type SCH layer 9, a spacer layer 11, an electron barrier layer 13, a p-type cladding layer 17, and a p-type contact layer 19 are grown on a substrate 1 in the stated order from the bottom upwards. As illustrated in FIG. 1, the semiconductor multilayer structure includes a mesa structure, and a buried layer 21 is placed on a side surface of the mesa structure. The p-type cladding layer 17 may include a diffraction grating layer 15. The diffraction grating layer 15 has a diffraction grating structure as illustrated in FIG. 1, and is placed discretely. The semiconductor laser may include two electrodes for injecting a current to the MQW 7, but illustration of those electrodes is omitted here. Although the layers close to the substrate 1 may be of the “n” type in the first example implementation, the semiconductor laser is not limited thereto, and the “n” type and the “p” type may be reversed.

The substrate 1, the n-type cladding layer 3, the spacer layer 11, and the p-type cladding layer 17 are formed from InP. The n-type SCH layer 5, the MQW 7, and the p-type SCH layer 9 are formed from InGaAsP. The n-type SCH layer 5, the MQW 7, or the p-type SCH layer 9 may be formed from InGaAs. In the MQW 7, well layers and barrier layers are alternately placed. Compressive strain is applied to the MQW 7. The electron barrier layer 13 is formed from InAlAs. Tensile strain is applied to the electron barrier layer 13. The application of tensile strain to the electron barrier layer 13 is achieved by, for example, changing a lattice constant of the electron barrier layer 13 through adjustment of a composition of In, Al, and As in InAlAs so that there is a difference in lattice constant between the electron barrier layer 13 and the spacer layer 11. That is, “applying tensile strain to the electron barrier layer” refers to giving tensile strain to the electron barrier layer 13 by artificially adjusting the composition of In, Al, and As in InAlAs. The p-type contact layer 19 is formed from InGaAs. The material of the p-type contact layer 19 is an example, and other materials may be used. The diffraction grating layer 15 is formed from InGaAsP. The n-type SCH layer 5 and/or the p-type SCH layer 9 may be omitted. The substrate 1 may be configured so as to serve as an n-type cladding layer instead of forming the n-type cladding layer 3.

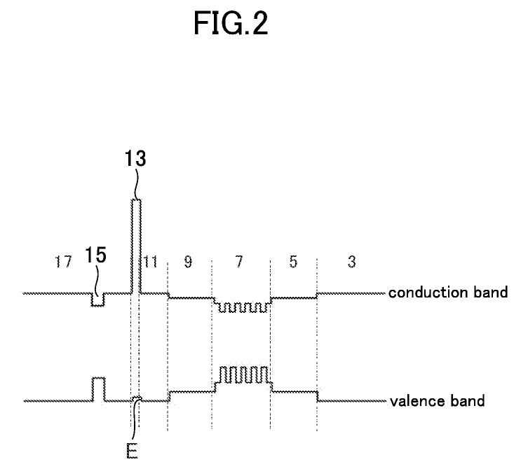

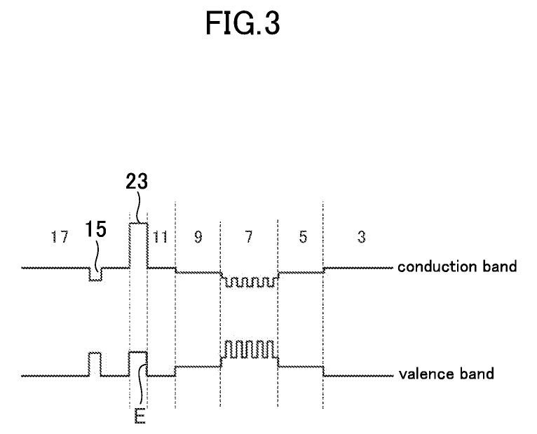

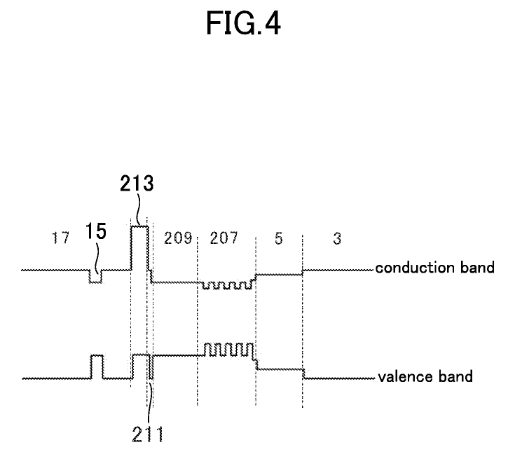

FIG. 2 a band diagram of a part of the semiconductor laser illustrated in FIG. 1 that is from the n-type cladding layer 3 to the p-type cladding layer 17. As a comparison example, a band diagram of a case (comparison example) in which the electron barrier layer 13 in the semiconductor laser of FIG. 1 is replaced with a strain-free electron barrier layer 23 to which no tensile strain is applied is illustrated in FIG. 3. FIG. 2 and FIG. 3 are band diagrams of heavy-hole bands, and the same applies to FIG. 4 through FIG. 7 described later. As is clear from FIG. 3, a flow of electrons moving from the n-type cladding layer 3 side to the p-type cladding layer 17 side is stemmed by the electron barrier layer 23. This is because there is an energy barrier between the spacer layer 11 and the electron barrier layer 23 in a conduction band. As a result, keeping electrons to the MQW 7 side is achieved. That is, overflow of electrons to the p-type cladding layer 17 side is suppressed. Meanwhile, there is an energy barrier E between the electron barrier layer 23 and the spacer layer 11 in a valence band, and holes are trapped in the electron barrier layer 23. That is, holes are hindered from flowing from the p-type cladding layer 17 to the MQW 7. Accordingly, a semiconductor laser of the comparison example illustrated in FIG. 3 is successful in improving optical output in high-temperature operation owing to the effect of suppressing the overflow of electrons, but is unsuccessful in obtaining a satisfactory level of optical output improving effect because the flow of holes is hindered by the energy barrier E.

In the semiconductor laser according to the first example implementation, the problem described above is solved by applying tensile strain to the electron barrier layer 13. Specifically, tensile strain is applied to the electron barrier layer 13 in an amount of 1.5%. A tensile strain amount of 1.5% is noted as “a strain amount of −1.5%” in some places. A strain amount noted with a minus sign indicates that the strain amount is the amount of tensile strain. A strain amount noted with a plus sign indicates that the strain amount is the amount of compressive strain. When tensile strain is applied, a band structure of the electron barrier layer 13 changes as illustrated in FIG. 2. Specifically, there are three changes: widening of a band gap; an increase in energy difference between a highest energy level of the electron barrier layer 13 and a highest energy level of the spacer layer 11 in the conduction band; and a reduction in energy difference between the highest energy level of the electron barrier layer 13 and the highest energy level of the spacer layer 11 in the valence band which results in diminishing of the energy barrier E. When the tensile strain amount is set to 1.5%, the energy difference between the highest energy level of the electron barrier layer 13 and the highest energy level of the spacer layer 11 in the valence band becomes very small, and the electron barrier layer 13 substantially stops hindering the flow of holes.

Application of tensile strain to the electron barrier layer 13 diminishes the energy barrier E. In order to obtain a satisfactorily high output characteristic in high-temperature operation compared to the structure in which the electron barrier layer 13 is free of strain, a preferred tensile strain amount of the electron barrier layer 13 is 1% or more. Note that application of tensile strain increases a difference in crystal lattice interval between the electron barrier layer 13 and the spacer layer 11. At worst, application of tensile strain causes crystal defects, and the tensile strain amount of the electron barrier layer 13 is accordingly preferred to be 2% or less. It is also undesirable for a highest energy level of the p-type SCH layer 9 to exceed the highest energy level of the electron barrier layer 13 in the valence band. Accordingly, the amount of tensile strain to be applied to the electron barrier layer 13 is preferred to be set so that the highest energy level of the electron barrier layer 13 in the valence band is approximately equal to or more than the highest energy level of the p-type SCH layer 9. Nevertheless, in a case in which the highest energy level of the p-type SCH layer 9 exceeds the highest energy level of the electron barrier layer 13 in the valence band by 26 meV, which is thermal energy of room temperature, substantially no obstacle is presented to the flow of holes. Accordingly, “approximately equal to or more than” here means that the highest energy level of the electron barrier layer 13 in the valence band is equal to or more than an energy level that is lower than the highest energy level of the p-type SCH layer 9 by 26 meV. In other words, a composition wavelength of the p-type SCH layer 9 may be desirably set so as to avoid generation of an energy barrier for holes between the electron barrier layer 13 and the p-type SCH layer 9.

In order to suppress generation of crystal defects, a thickness of the electron barrier layer 13 is required to be equal to or less than a critical thickness. For example, when the strain amount is −1.5%, the critical thickness is 30nm, and the thickness of the electron barrier layer 13 is accordingly set here to 15nm. In a case in which the thickness of the electron barrier layer 13 is less than 10nm, on the other hand, a tunnel effect comes into force and weakens the effect of suppressing overflow of electrons. Accordingly, in a case of applying tensile strain to the electron barrier layer 13, the thickness of the electron barrier layer 13 is desirably set equal to or more than 10nm and equal to or less than the critical thickness.

A layer other than the p-type SCH layer 9 may be placed between the MQW 7 and the spacer layer 11. In the case of placing another layer as well, a composition wavelength of the layer is desirably set so that the highest energy level of the layer is an energy level at which generation of an energy barrier for holes is avoided between the layer and the electron barrier layer 13.

As is clear from FIG. 2, the effect obtained by applying tensile strain to the electron barrier layer 13 is obtained also in the conduction band. In comparison to FIG. 3, an energy barrier presented by the electron barrier layer 13 to electrons is higher than the energy barrier presented by the electron barrier layer 23 to electrons. For that reason, the optical semiconductor device according to the first example implementation is high in the effect of suppressing overflow of electrons as well.

In the valence band, there is an energy barrier also between the diffraction grating layer 15 and the p-type cladding layer 17. However, the diffraction grating layer 15 may be placed discretely as illustrated in FIG. 1. The p-type cladding layer 17 is placed in a region in which no diffraction grating layer 15 is placed, and there is no energy barrier in this region. Accordingly, holes can smoothly flow into the MQW 7 by traveling through the region in which no diffraction grating layer 15 is placed. Further, the electron barrier layer 13 may be preferred to be placed below (a downward direction in FIG. 1) the diffraction grating layer 15. In other words, the electron barrier layer 13 may be preferred to be grown prior to the diffraction grating layer 15 in a growth order of crystal growth. The diffraction grating layer 15 may have the diffraction grating structure as described above. When the p-type cladding layer 17 grows on the diffraction grating structure, a concave-convex structure is sometimes formed on a surface of the p-type cladding layer 17. The concave-convex structure may affect crystal quality of the electron barrier layer 13 in a case in which the electron barrier layer 13 with high tensile strain applied thereto may be placed above the concave-convex structure. The electron barrier layer 13 may be accordingly preferred to be placed on a flat layer.

The semiconductor layer may be a CW laser which emits continuous light or a directly-modulated laser which outputs modulated light. The optical semiconductor device may be an optical amplifier. When the optical semiconductor device is an optical amplifier, the diffraction grating layer 15 is omitted. In the following embodiments, a case in which the optical semiconductor device is a semiconductor laser is described.

FIG. 4 is a band diagram of a part of a semiconductor laser according to a second example implementation of the present invention that is from the n-type cladding layer 3 to the p-type cladding layer 17. Differences from the semiconductor laser according to the first example implementation are a composition wavelength of a barrier layer of an MQW 207 and a composition wavelength of a p-type SCH layer 209, a thickness of a spacer layer 211, and a structure of an electron barrier layer 213.

The electron barrier layer 213 is a layer formed from InAlAs to which no tensile strain is applied as in the comparison example of FIG. 3. Although there may be natural and unavoidable generation of tensile strain in the electron barrier layer 213, “no tensile strain is applied” here means that there is no tensile strain that is applied to the electron barrier layer 213 as a result of artificially adjusting the composition of In, Al, and As in InAlAs in the manner described above. With no tensile strain applied to the electron barrier layer 213, there is an energy barrier between the electron barrier layer 213 and the spacer layer 211 in the valence band. However, in the second example implementation, the spacer layer 211 is set to have a thickness at which a satisfactory level of tunnel effect is obtained. The tunnel effect is observed generally at a thickness that is less than 10nm, and the thickness of the spacer layer 211 is accordingly set here to 5nm. Further, the composition wavelength of the p-type SCH layer 209 is set to the wavelength of a wave longer than in the first example implementation. Specifically, the p-type SCH layer 209 is set to have a composition wavelength at which substantially no energy barrier is generated between the p-type SCH layer 209 and the strain-free electron barrier layer 213 formed from InAlAs in the valence band. When band discontinuity between the electron barrier layer 213 and the p-type SCH layer 209 in the valence band is equal to or less than 26 meV which is the thermal energy of room temperature, hole injection in driving is practically not hindered. For example, when the p-type SCH layer 209 is formed from InGaAsP, the composition wavelength of the p-type SCH layer 209 is set to 1.15μm or higher. As in the first example implementation, the above-mentioned limitation to 26 meV or less is not required to be taken into consideration when a highest energy level of the p-type SCH layer 209 is lower than a highest energy level of the electron barrier layer 213 in the valence band. That is, it is sufficient for the highest energy level of the electron barrier layer 213 to be approximately equal to or more than the highest energy level of the p-type SCH layer 209. Further, the composition wavelength of the barrier layer of the MQW 207 may be preferred to be set to the composition wavelength of the p-type SCH layer 209 or higher in order to avoid generation of an energy barrier between the p-type SCH layer 209 and the barrier layer of the MQW 207. Here, the p-type SCH layer 209 and the barrier layer of the MQW 207 are set to have the same composition wavelength.

In the second example implementation, holes traveling from the p-type cladding layer 17 toward the MQW 207 are trapped once by the electron barrier layer 213 in the valence band because of the energy barrier between the electron barrier layer 213 and the spacer layer 211. However, the holes slip through the spacer layer 211 due to the tunnel effect, and travel to the p-type SCH layer 209. That is, although there is an energy difference between the electron barrier layer 213 and the spacer layer 211, there is practically no energy barrier for holes. Further, in a case in which an energy barrier exists between the electron barrier layer 213 and the p-type SCH layer 209, the holes enabled by the tunnel effect to slip through the spacer layer 211 cannot reach the p-type SCH layer 209 beyond the spacer layer 211. Accordingly, the composition wavelength of the p-type SCH layer 209 is set to 1.15μm or higher. Further, the composition wavelength of the barrier layer of the MQW 207 is set to the composition wavelength of the p-type SCH layer 209 or higher because the presence of an energy barrier between the p-type SCH layer 209 and the barrier layer of the MQW 207 is undesirable as well. With those configurations, generation of an energy barrier for holes is avoided in the valence band from the electron barrier layer 213 to a well layer of the MQW 207, and excellent characteristics in high-temperature operation are thus achieved. The spacer layer 211 is preferred to have a thickness of 3 nm or more from the viewpoint of crystal quality.

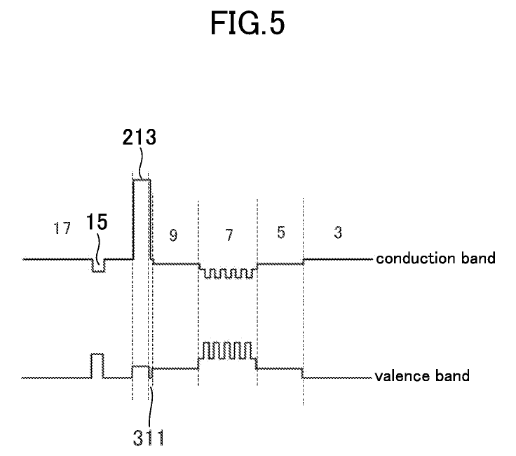

FIG. 5 is a band diagram of a part of a semiconductor laser according to a third example implementation of the present invention that is from the n-type cladding layer 3 to the p-type cladding layer 17. Differences from the semiconductor laser according to the first example implementation are a thickness of a spacer layer 311 and a strain amount of an electron barrier layer 313.

The thickness of the spacer layer 311 is, as in the second example implementation, less than 10nm at which the tunnel effect comes into force. Here, the spacer layer 311 has a thickness of 5nm. A tensile strain amount of the electron barrier layer 313 is set to 1% (the strain amount is set to −1%). At this strain amount, however, an energy barrier is generated between the electron barrier layer 313 and the spacer layer 311 as in the second example implementation. Still, as in the second example implementation, the spacer layer 311 is set to have a thickness at which a satisfactory level of tunnel effect is obtained, and holes can accordingly slip through the spacer layer 311. In addition, the p-type SCH layer 9 is set to have a composition wavelength that causes substantially no energy barrier between the p-type SCH layer 9 and the electron barrier layer 313 (an energy difference therebetween is 26 meV or less). The composition wavelength of the p-type SCH layer 9 here is 1.1μm. The composition wavelength of the barrier layer of the MQW 7 is set equal to or higher than the composition wavelength of the p-type SCH layer 9 in order to avoid generation of an energy barrier between the p-type SCH layer 9 and the barrier layer of the MQW 7. The third example implementation is the same as the second example implementation in that the holes slip through the spacer layer 311 due to the tunnel effect but is larger than the second example implementation in band offset between the well layer and the barrier layer of the MQW 7. This gives the optical semiconductor device according to the second example implementation a superior effect of suppressing overflow of electrons and holes from the MQW 7 in high-temperature operation.

The strain amount of the electron barrier layer 313 is thus allowed to be set to an appropriate amount suited to the composition of the p-type SCH layer 9 and the composition of the barrier layer of the MQW 7 so that no energy barrier is generated for holes. For example, in the case of combining the electron barrier layer 313 with the spacer layer 311 having a thickness that causes the tunnel effect, the strain amount of the electron barrier layer 313 is preferred to be a tensile strain amount of 0.5% or more. However, as in the first example implementation, the tensile strain amount is preferred to be 2% or less from the viewpoint of crystal quality.

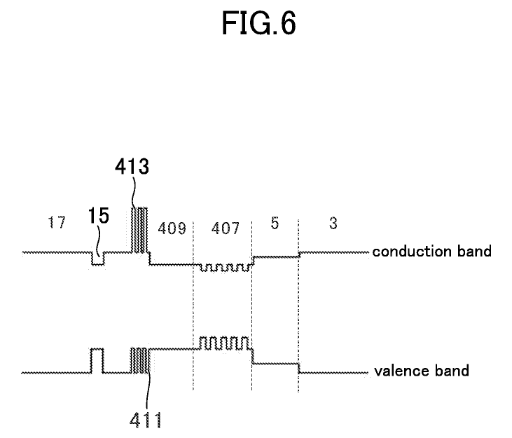

FIG. 6 is a band diagram of a part of a semiconductor laser according to a fourth example implementation of the present invention that is from the n-type cladding layer 3 to the p-type cladding layer 17. Differences from the semiconductor laser according to the first example implementation are a composition wavelength of a barrier layer of an MQW 407 and a composition wavelength of a p-type SCH layer 409, a structure of a spacer layer 411, and a structure of an electron barrier layer 413.

As in the second example implementation, the spacer layer 411 has a thickness at which a satisfactory level of tunnel effect is obtained. The electron barrier layer 413 is a layer formed from InAlAs to which no strain is applied on purpose, and is set to have a thickness at which a satisfactory level of tunnel effect is obtained. Here, the spacer layer 411 and the electron barrier layer 413 each may have a thickness of 5nm. However, this is merely an example, and each of the spacer layer 411 and the electron barrier layer 413 may be set to have another thickness that is less than 10nm and equal to or more than 3nm. The thickness of the spacer layer 411 and the thickness of the electron barrier layer 413 may differ from each other. A plurality of the spacer layers 411 and a plurality of the electron barrier layers 413 are alternately and continuously placed to form a quasi-MQW structure. Here, three sets of the spacer layer 411 and the electron barrier layer 413 are placed side by side. This number of sets is merely an example.

The composition wavelength of the p-type SCH layer 409 is set to, as in the second example implementation, equal to or more than 1.15μm at which generation of an energy barrier for holes is avoided between the electron barrier layer 413 and the p-type SCH layer 409. Similarly, the composition wavelength of the barrier layer of the MQW 407 is set so as to avoid generation of an energy barrier for holes between the barrier layer of the MQW 407 and the p-type SCH layer 409.

A probability of the tunnel effect for holes coming into force is increased from the second example implementation by adopting the quasi-MQW structure in which the spacer layer 411 and the electron barrier layer 413 alternate with each other, and, consequently, the holes flow more smoothly to the MQW 407. There is a fear of electrons slipping through the electron barrier layer 413 and reaching the p-type cladding layer 17 in the conduction band as well due to the tunnel effect. However, as is clear from FIG. 6, there is a sufficient energy difference between the p-type SCH layer 409 and the electron barrier layer 413, and hence overflow of electrons is satisfactorily suppressed, with the result that a semiconductor laser exhibiting excellent high-temperature operation is achieved.

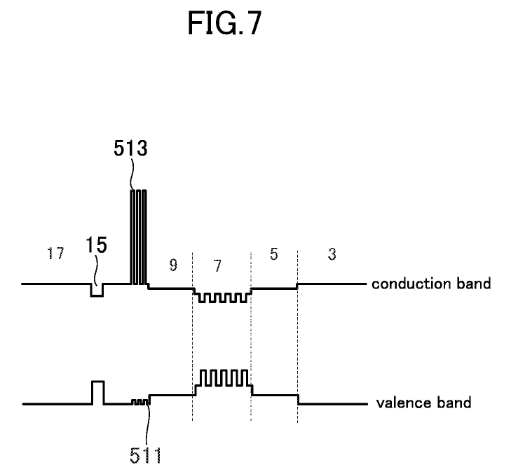

FIG. 7 is a band diagram of a part of a semiconductor laser according to a fifth example implementation of the present invention that is from the n-type cladding layer 3 to the p-type cladding layer 17. Differences from the semiconductor laser according to the first example implementation are a structure of a spacer layer 511 and a structure of an electron barrier layer 513.

In FIG. 7, a structure that is a sort of a combination of the third example implementation and the fourth example implementation may be illustrated. That is, a plurality of the spacer layers 511 and a plurality of the electron barrier layers 513 are alternately and continuously placed. The electron barrier layer 513 is set to have a strain amount that causes no energy barrier between the electron barrier layer 513 and the p-type SCH layer 9. For example, when the composition wavelength of the p-type SCH layer 9 is 1.15μm, the tensile strain amount of the electron barrier layer 513 is 1% or more. Here, the tensile strain amount of the electron barrier layer 513 is set to 1.5% (the strain amount is set to −1.5%). With this configuration, a very high energy barrier for electrons is achieved in the conduction band and, at the same time, an energy barrier for holes is satisfactorily diminished in the valence band, to thereby achieve a semiconductor laser that exhibits a high output characteristic in high-temperature operation.

The example implementations described above use a semiconductor laser as an example of the optical semiconductor device, but the optical semiconductor device is not limited thereto and may be an optical amplifier. A buried-type optical semiconductor device is given as an example of the optical semiconductor device of the example implementations described above, but the optical semiconductor device is not limited thereto. For example, the optical semiconductor device may be a ridge-type semiconductor in which the MQW is not included in the mesa structure. The optical semiconductor device may also adopt a structure in which the mesa structure includes the MQW but no buried layer is placed on a side surface of the mesa structure. The spacer layer and the electron barrier layer may have the p-type conductivity or may be undoped layers. However, in a case in which the p-type SCH layer is placed, it may be preferred that both of the spacer layer and the electron barrier layer be of the “p” type. Here, “having the p-type conductivity” includes not only having a structure that has been intentionally doped with impurities during crystal growth but also a case in which a layer that has been undoped during crystal growth assumes the p-type conductivity as a result of diffusion of a dopant from the p-type cladding layer in the process of crystal growth.

Some example implentations described herein improve an optical semiconductor device including a multiple-quantum well layer which may be formed from InGaAsP or InGaAs, an electron barrier layer which is formed from InAlAs, and a spacer layer which is placed between the multiple-quantum well layer and the electron barrier layer and which is formed from InP, in terms of characteristics in high-temperature operation, by diminishing an energy barrier between the electron barrier layer and the multiple-quantum well layer in a valence band. The improvement of characteristics in high-temperature operation is achieved particularly by diminishing an energy barrier that is generated between the electron barrier layer and the spacer layer. In some of the example implentations of the present invention, the energy barrier between the electron barrier layer and spacer layer is diminished by applying tensile strain to the electron barrier layer in an amount that is equal to or more than 1% and equal to or less than 2%, and thus increasing the energy of the electron barrier layer in the valence band. In a case in which another layer (for example, an SCH layer) is placed between the spacer layer and the multiple-quantum well layer, the SCH layer is set to have a composition wavelength at which generation of an energy barrier for holes is avoided between the electron barrier layer and the SCH layer. Further, in another example implementation, the spacer layer is set to have a thickness that is less than 10nm, to thereby create a state in which, even when there is an energy barrier between the electron barrier layer and the spacer layer, holes slip through the spacer layer due to the tunnel effect and, accordingly, there is substantially no energy barrier. The same effect is obtainable by setting each of the electron barrier layer and the spacer layer to have a thickness that is less than 10nm, and placing a plurality of electron barrier layers and a plurality of spacer layers alternately and continuously. A spacer layer having a thickness at which a satisfactory level of tunnel effect is obtained and an electron barrier layer to which tensile strain is applied may be used in combination.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature’s relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical semiconductor device, comprising:
a multiple-quantum well layer which is formed from one of InGaAsP or InGaAs and which includes a well layer and a barrier layer;
an electron barrier layer formed from InAlAs;
a spacer layer which is placed between the multiple-quantum well layer and the electron barrier layer, and which is formed from InP; and
an optical confinement layer placed between the multiple-quantum well layer and the spacer layer,
wherein the electron barrier layer has a highest energy level that is approximately equal to or more than a highest energy level of the optical confinement layer in a valence band.

2. The optical semiconductor device according to claim 1, wherein, in the valence band, the highest energy level of the electron barrier layer is equal to or more than an energy level that is lower than the highest energy level of the optical confinement layer by 26 meV.

3. The optical semiconductor device according to claim 1, wherein the electron barrier layer receives application of tensile strain in an amount that is 1% or more.

4. The optical semiconductor device according to claim 3, wherein the amount of tensile strain of the electron barrier layer is 2% or less.

5. The optical semiconductor device according to claim 3, wherein the electron barrier layer has a thickness that is equal to or more than 10 nm and equal to or less than a critical thickness.

6. The optical semiconductor device according to claim 3, further comprising a substrate and a diffraction grating layer,
wherein the multiple-quantum well layer, the optical confinement layer, the spacer layer, the electron barrier layer, and the diffraction grating layer are placed on the substrate in the stated order.

7. The optical semiconductor device according to claim 1, wherein the spacer layer has a thickness that is less than 10 nm.

8. The optical semiconductor device according to claim 7, wherein the spacer layer has a thickness that is equal to or more than 3 nm.

9. The optical semiconductor device according to claim 7, wherein the electron barrier layer receives no application of tensile strain.

10. The optical semiconductor device according to claim 9,
wherein the optical confinement layer is placed between the spacer layer and the barrier layer, and
wherein the optical confinement layer has a composition wavelength of 1.15 μm or higher.

11. The optical semiconductor device according to claim 7, wherein the electron barrier layer receives application of tensile strain.

12. The optical semiconductor device according to claim 11, wherein an amount of tensile strain of the electron barrier layer is 0.5% or more.

13. The optical semiconductor device according to claim 1,
wherein a plurality of the electron barrier layers and a plurality of the spacer layers are placed alternately and continuously, and
wherein the electron barrier layer and the spacer layer each have a thickness that is less than 10 nm.

14. The optical semiconductor device according to claim 13, wherein the electron barrier layer receives no application of tensile strain.

15. The optical semiconductor device according to claim 13, wherein the optical confinement layer has a composition wavelength of 1.15 μm or higher.

16. The optical semiconductor device according to claim 13, wherein the electron barrier layer receives application of tensile strain.

17. The optical semiconductor device according to claim 16, wherein an amount of tensile strain of the electron barrier layer is 0.5% or more.

18. The optical semiconductor device according to claim 1, wherein the multiple-quantum well layer receives application of compressive strain.

19. The optical semiconductor device according to claim 1, wherein the spacer layer is of a “p” type.

20. The optical semiconductor device according to claim 19, wherein the electron barrier layer is of the “p” type.
